(19) United States
(12) Patent Application Publication
(10) Pub. No.: US 2015/0368829 A1
(43) Pub. Date: Dec. 24, 2015

(54) SUBSTRATE THERMAL CONTROL IN AN EPI CHAMBER

(71) Applicant: Applied Materials, Inc., Santa Clara, CA (US)

(72) Inventors: Anhthu NGO, San Jose, CA (US); Schubert S. CHU, San Francisco, CA (US); Nyi O. MYO, San Jose, CA (US); Paul BRILLHART, Pleasanton, CA (US); Yi-Chiau HUANG, Fremont, CA (US); Zuoming ZHU, Sunnyvale, CA (US); Kevin Joseph BAUTISTA, San Jose, CA (US); Kartik SHAH, Sunnyvale, CA (US); Edric TONG, Sunnyvale, CA (US); Xuebin LI, Sunnyvale, CA (US); Zhepeng CONG, Vancouver, WA (US); Balasubramanian RAMACHANDRAN, Santa Clara, CA (US)

(21) Appl. No.: 14/745,979

(22) Filed: Jun. 22, 2015

Related U.S. Application Data
(60) Provisional application No. 62/015,953, filed on Jun. 23, 2014.

(51) Int. Cl. C30B 25/12

(52) U.S. Cl. CPC C30B 25/12

(57) ABSTRACT

In one embodiment, a susceptor for a thermal processing chamber is provided. The susceptor includes a base having a front side and a back side made of a thermally conductive material opposite the front side, wherein the base includes a peripheral region surrounding a recessed area having a thickness that is less than a thickness of the peripheral region, and a plurality of raised features protruding from one or both of the front side and the back side.

### CROSS-REFERENCE TO RELATED APPLICATIONS

This application claims benefit of U.S. Provisional Patent Application Ser. No. 62/015,953 (Attorney Docket No. 022048USL02) filed June 23, 2014, which is hereby incorporated by reference herein.

### FIELD

Embodiments disclosed herein generally relate to a susceptor for thermal processing of semiconductor substrates, and more particularly to a susceptor having features to improve thermal uniformity across a substrate during processing.

### BACKGROUND

Semiconductor substrates are processed for a wide variety of applications, including the fabrication of integrated devices and mirco-devices. One method of processing substrates includes depositing a material, such as a dielectric material or a conductive metal, on an upper surface of the substrate. Epitaxy is one deposition process that is used to grow a thin, ultra-pure layer, usually of silicon or germanium on a surface of a substrate in a processing chamber. Epitaxy processes are able to produce such quality layers by maintaining highly uniform process conditions, such as temperature, pressures, and flow rates, within the processing chambers. Maintaining highly uniform process condition in areas around the upper surface of the substrate is necessary for producing the high-quality layers.

Susceptors are often used in epitaxy processes to support the substrate as well as heat the substrate to a highly uniform temperature. Susceptors often have platter or dish-shaped upper surfaces that are used to support a substrate from below around the edges of the substrate while leaving a small gap between the remaining lower surface of the substrate and the upper surface of the susceptor. Precise control over a heating source, such as a plurality of heating lamps disposed below the susceptor, allows a susceptor to be heated within very strict tolerances. The heated susceptor can then transfer heat to the substrate, primarily by radiation emitted by the susceptor.

Despite the precise control of heating the susceptor in epitaxy, temperature non-uniformities persist across the upper surface of the substrate often reducing the quality of the layers deposited on the substrate. Undesirable temperature profiles have been observed near the edges of the substrate as well as over areas closer to the center of the substrate. Therefore, a need exists for an improved susceptor for supporting and heating substrates in semiconductor processing.

### SUMMARY

In one embodiment, a susceptor for a thermal processing chamber is provided. The susceptor includes a base having a front side and a back side made of a thermally conductive material opposite the front side, wherein the base includes a peripheral region surrounding a recessed area having a thickness that is less than a thickness of the peripheral region, and a plurality of raised features protruding from one or both of the front side and the back side.

In another embodiment, a susceptor for a thermal processing chamber is provided. The susceptor includes a base made of a thermally conductive material, and having a front side and a back side opposite the front side. The base further includes a peripheral region surrounding a recessed area having a thickness that is less than a thickness of the peripheral region, and a plurality of raised features protruding from one or both of the front side and the back side. The susceptor also includes a ring made of a thermally conductive material, wherein the peripheral region has an insert region to receive the ring.

In another embodiment, a susceptor for a thermal processing chamber is provided. The susceptor includes a base having a front side and a back side opposite the front side made of a thermally conductive material. The base includes a peripheral region surrounding a recessed area having a thickness that is less than a thickness of the peripheral region. The susceptor also includes a ring made of a thermally conductive material and having a sloped surface formed on an inner circumference thereof to facilitate centering of a substrate thereon, wherein the peripheral region has an insert region to receive the ring.

### BRIEF DESCRIPTION OF THE DRAWINGS

So that the manner in which the above recited features of the embodiments disclosed above can be understood in detail, a more particular description, briefly summarized above, may be had by reference to the following embodiments, some of which are illustrated in the appended drawings. It is to be noted, however, that the appended drawings illustrate only typical embodiments and are therefore not to be considered limiting of its scope to exclude other equally effective embodiments.

FIG. 1 illustrates a schematic sectional view of a process chamber according to one embodiment.

FIG. 2A is a perspective view of a susceptor that may be used in the process chamber of FIG. 1, according to one embodiment.

FIG. 2B is a top view of the susceptor of FIG. 2A.

FIG. 2C is a partial cross-sectional view of the susceptor of FIG. 2B.

FIGS. 3A and 3B are isometric views of a susceptor that may be used in the process chamber of FIG. 1, according to another embodiment.

FIG. 3C shows another embodiment of a susceptor that may be used in the process chamber of FIG. 1.

FIG. 4A is a top cross-sectional view that shows one embodiment of a susceptor and a circular shield that may be used in the process chamber of FIG. 1.

FIG. 4B shows another embodiment of a susceptor and a circular shield that may be used in the process chamber of FIG. 1.

FIG. 5 is a plan view of a backside of another embodiment of a susceptor that may be used in the process chamber of FIG. 1.

FIGS. 6A-6C are various views of another embodiment of a susceptor that may be used in the process chamber of FIG. 1.

FIG. 7 is a side cross-sectional view of another embodiment of a susceptor that may be used in the process chamber of FIG. 1.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The embodiments disclosed generally relate to a susceptor for thermal processing of semiconductor substrates. The embodiments disclosed can improve thermal uniformity across the surface of a substrate during processing by reducing a contacting surface area between the susceptor and the substrate. Reducing the contacting surface area between the susceptor and the substrate reduces the amount of heat that is transferred from the susceptor to the substrate by conduction during processing. Embodiments of some structures that can reduce the contacting surface area between the substrate and the susceptor are described below.

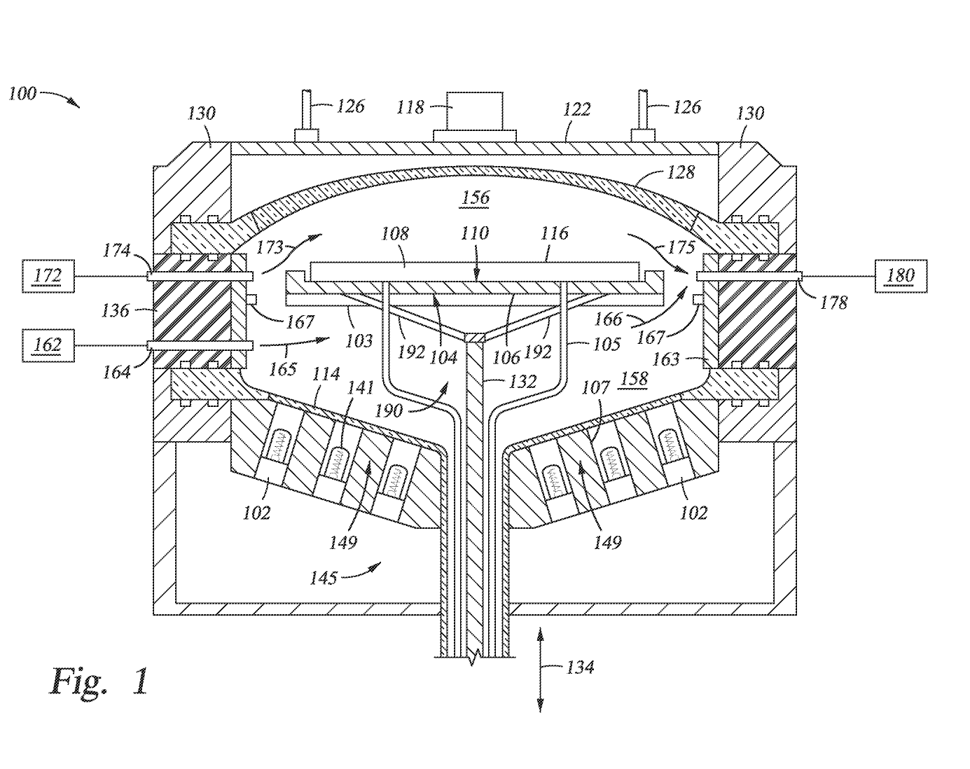

FIG. 1 is a schematic sectional view of a process chamber 100 according to one embodiment. A susceptor 106 is located within the process chamber 100 between an upper dome 128 and a lower dome 114. The process chamber 100 may be used to process one or more substrates, including the deposition of a material on an upper surface of a substrate 108. The process chamber 100 may include an array of radiant heating lamps 102 for heating, among other components, a back side 104 of the susceptor 106 disposed within the process chamber 100. In some embodiments, the array of radiant heating lamps may be disposed over the upper dome 128.

The upper dome 128, the lower dome 114 and a base ring 136 that is disposed between the upper dome 128 and lower dome 114 generally define an internal region of the process chamber 100. The substrate 108 (not to scale) can be brought into the process chamber 100 and positioned onto the susceptor 106 through a loading port 103. The susceptor 106 is shown in an elevated processing position supported by a central shaft 132. However, the susceptor 106 may be vertically traversed by an actuator (not shown) to a loading position below the processing position. In one embodiment, lowering the susceptor 106 on the central shaft 132 allows lift pins 105 to contact the lower dome 114. The lift pins 105, passing through holes in the susceptor 106, raise the substrate 108 from the susceptor 106. A robot (not shown) may then enter the process chamber 100 to engage and remove the substrate 108 therefrom though the loading port 103. The susceptor 106 then may be actuated up to the processing position to place the substrate 108, with a device side 116 facing up, on a front side 110 of the susceptor 106. The susceptor 106 may be supported by a substrate support 190. The substrate support 190 includes at least three support arms 192 (only two are shown).

The susceptor 106, while located in the processing position, divides the internal volume of the process chamber 100 into a process gas region 156 that is above the substrate, and a purge gas region 158 below the susceptor 106. The susceptor 106 may be rotated during processing by the central shaft 132. The rotation may be utilized to minimize the effect of thermal and process gas flow spatial anomalies within the process chamber 100 and thus facilitate uniform processing of the substrate 108. The susceptor 106 is supported by the central shaft 132, which moves the substrate 108 in an up and down direction 134 during loading and unloading as described above. In some embodiments, the susceptor 106 may be moved in an up and down direction during processing of the substrate 108.

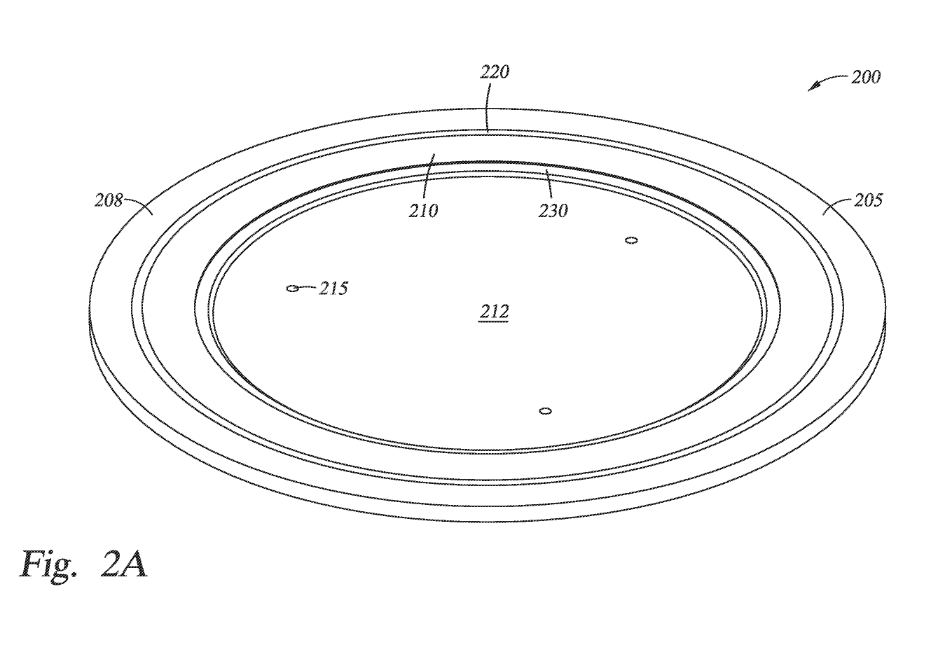

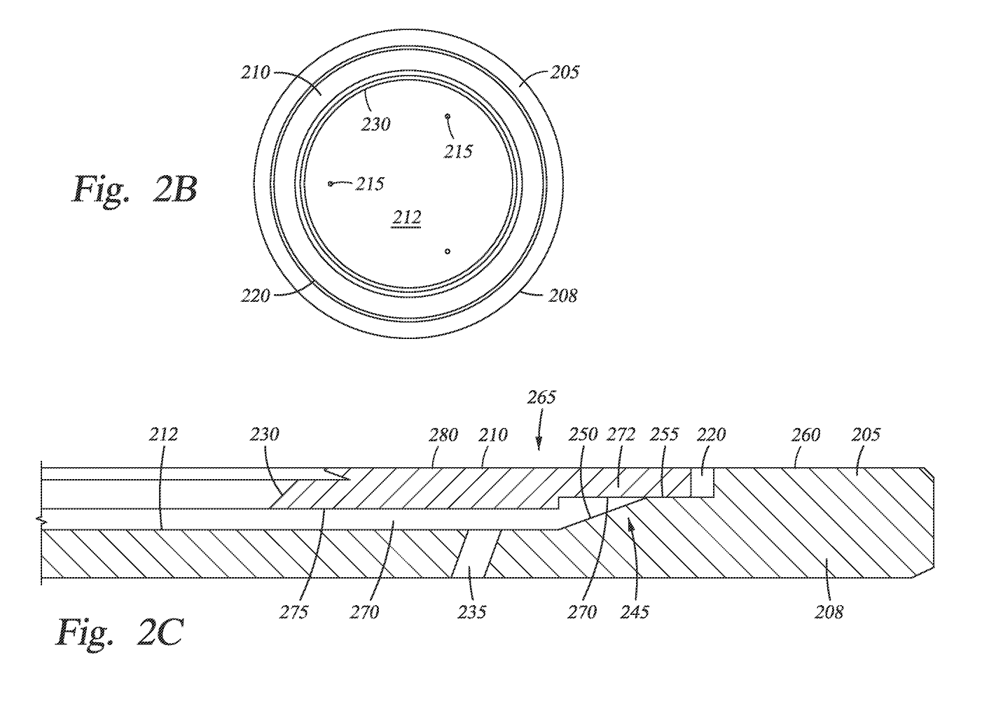

The susceptor 106 may be formed from silicon carbide or graphite coated with silicon carbide to absorb radiant energy from the lamps 102 and conduct the radiant energy to the substrate 108. In general, the central window portion of the upper dome 128 and the bottom of the lower dome 114 are formed from an optically transparent material such as quartz. As will be discussed in more detail below with respect to FIG. 2A, the thickness and the degree of curvature of the upper dome 128 may be configured in accordance with this disclosure to provide a flatter geometry for uniform flow uniformity in the process chamber.

The lamps 102 may be configured to include bulbs 141 and be configured as an array. The lamps 102 may be used to heat the substrate 108 to a temperature within a range of about 200 degrees Celsius to about 1,600 degrees Celsius. An optical pyrometer 118 may be used for temperature measurements/control on the substrate 108. Each lamp 102 is coupled to a power distribution board (not shown) through which power is supplied to each lamp 102. The lamps 102 may be contained within a lamphead 145. The lamphead 145 may be cooled during or after processing by, for example, a cooling fluid introduced into channels 149 located between the lamps 102. The lamphead 145 may conductively and radiatively cool the lower dome 104 due in part to the close proximity of the lamphead 145 to the lower dome 104. The lamphead 145 may also cool the lamp walls and walls of reflectors 107 around the lamps. Alternatively, the lower dome 104 may be cooled by a convective approach. Depending upon the application, the lamps 102 may or may not be in contact with the lower dome 114.

Process gas supplied from a process gas supply source 172 is introduced into the process gas region 156 through a process gas inlet 174 formed in the sidewall of the base ring 136. The process gas inlet 174 is configured to direct the process gas in a generally radially inward direction. During the film formation process, the susceptor 106 may be located in the processing position, which is adjacent to and at about the same elevation as the process gas inlet 174.

The position allows the process gas to flow along flow path 173 across the upper surface of the substrate 108 in a laminar flow manner. The process gas exits the process gas region 156 (along flow path 175) through a gas outlet 178 located on the side of the process chamber 100 opposite the process gas inlet 174. Removal of the process gas through the gas outlet 178 may be facilitated by a vacuum pump 180 coupled thereto. Radial deposition uniformity may be provided by the rotation of the substrate 108 during processing. The lamps 102 can be disposed adjacent to and beneath the lower dome 114 in a specified, optimal desired manner around the central shaft 132 to independently control the temperature at various regions of the substrate 108 as the process gas passes over, thereby facilitating the deposition of a material onto the upper surface of the substrate 108. While not discussed here in detail, the deposited material may include gallium arsenide, gallium nitride, or aluminum gallium nitride.

A circular shield 167 or a preheat ring may be optionally disposed around the susceptor 106. The susceptor 106 may also be surrounded by a liner assembly 163. The shield 167 prevents or minimizes leakage of heat/light noise from the lamps 102 to the device side 116 of the substrate 108 while providing a pre-heat zone for the process gases. The liner assembly 163 shields the processing volume (i.e., the process gas region 156 and purge gas region 158) from metallic walls of the process chamber 100. The metallic walls may react with precursors and cause contamination in the processing volume. The shield 167 and/or the liner assembly 163 may be made from CVD SiC, sintered graphite coated with SiC, grown SiC, opaque quartz, coated quartz, or any similar, suitable material that is resistant to chemical breakdown by process and purging gases.

A reflector 122 may be optionally placed outside the upper dome 128 to reflect infrared light that is radiating off the substrate 108 back onto the substrate 108. The reflector 122 may be secured to the upper dome 128 using a clamp ring 130. The reflector 122 can be made of a metal such as aluminum or stainless steel. The efficiency of the reflection can be improved by coating a reflector area with a highly reflective coating such as gold. The reflector 122 can have one or more channels 126 for connection to a cooling source (not shown). The channel 126 connects to a passage (not shown) formed on a side of the reflector 122. The passage is configured to carry a flow of a fluid such as water and may run horizontally along the side of the reflector 122 in any desired pattern covering a portion or entire surface of the reflector 122 for cooling the reflector 122.

FIG. 2A is a perspective view of a susceptor 200, according to one embodiment, that may be used as the susceptor 106 shown in FIG. 1. FIG. 2B is a top view of the susceptor 200 of FIG. 2A, and FIG. 2C is a partial cross-sectional view of the susceptor 200 of FIG. 2B.

The susceptor 200 includes a base 205 and a ring 210 that rests on the base 205. Lift pin holes 215 are also formed in the base. The base 205 and the ring 210 may be made of similar or different materials. The materials include deposited SiC, sintered graphite coated with SiC, grown SiC, opaque quartz, coated quartz, or any similar, suitable material that is resistant to chemical breakdown by process and purge gases. The ring 210 also includes a sloped surface 230 that may be used to support an edge of a substrate (not shown). The base 205 includes a peripheral region 208 surrounding a recessed area 212. As shown in FIG. 2C, a thickness of the peripheral region 208 is greater than a thickness of the recessed area 212.

In operation, contact with a substrate is made only between portions of the ring 210 and the base 205, which provides minimal conduction of heat between the ring 210 and the base 205. The ring 210 reduces a contacting surface area between the substrate and the base 205 of the susceptor 200, which reduces thermal conduction into the edge of the substrate from the susceptor 200. A gap 220 may also be formed between the base 205 and the ring 210 to minimize contact therebetween. The gap 220 may also be used to compensate for differences in thermal expansion between different materials if the ring 210 is a different material from the base 205. The sloped surface 230 may be formed on an inner circumference of the ring 210 to facilitate centering of a substrate. Additionally, an optional gap 240 (shown in FIG. 2C) may be provided between the ring 210 and the base 205. Optionally or additionally, the base 205 may have vent holes 235 formed therein (only one is shown in FIG. 2C). The base 205 may also include a stepped region 245. The stepped region 245 may include one or both of a sloped surface 250 and a shoulder region 255. The stepped region 245 transitions between a surface 260 of the peripheral region 208 and the recessed area 212. The ring 210 may also include a stepped region 265. The stepped region 265 may include a recessed surface 270 along a peripheral edge region 272 that transitions to an interior ring region 275. A thickness of the peripheral edge region 272 is less than a thickness of the interior ring region 275. The ring 210 also includes a surface 280 that is substantially coplanar with the surface 260 of the peripheral region 208 of the base 205.

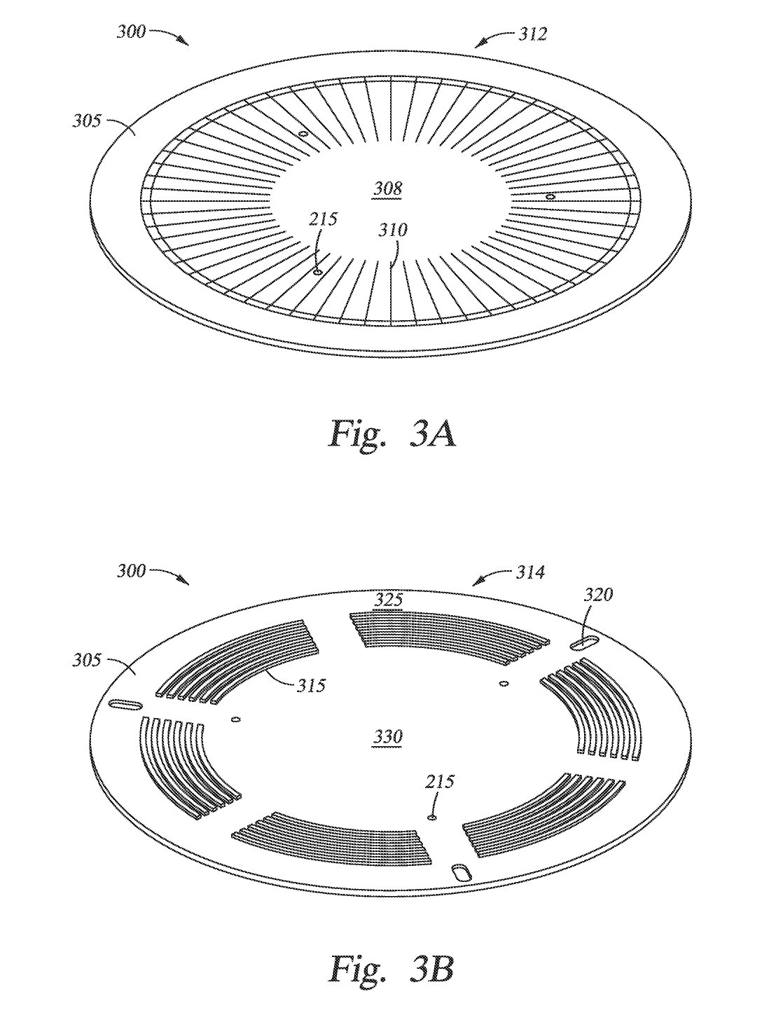

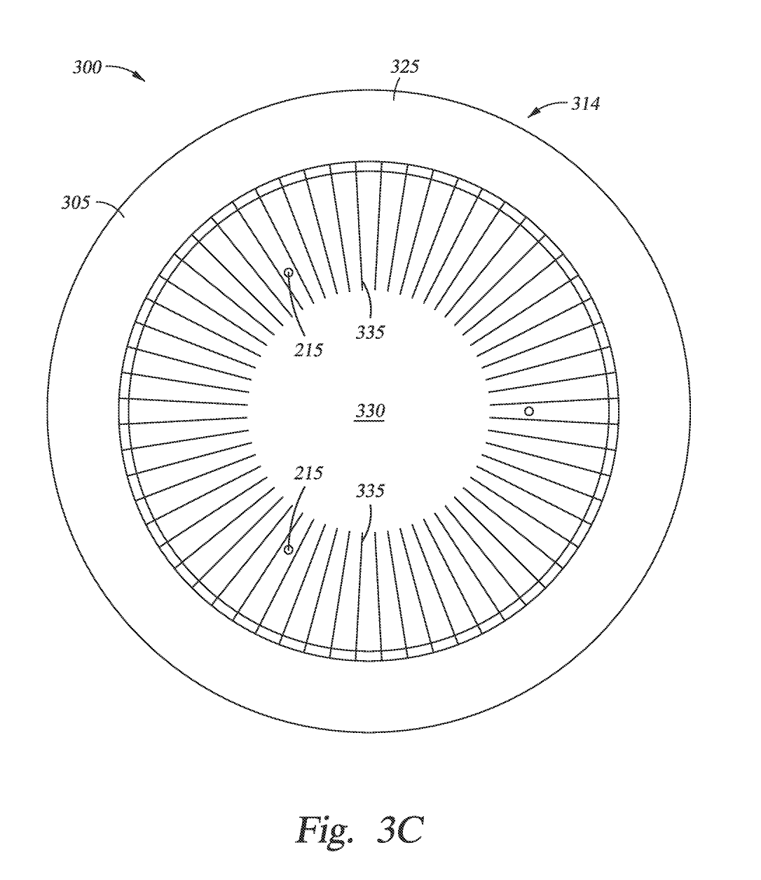

FIGS. 3A and 3B are isometric views of a susceptor 300, according to another embodiment. FIG. 3A shows a front side 312 (substrate receiving side) of the base 305 while FIG. 3B shows the back side 314 of the base 305. The susceptor 300 may be utilized as the susceptor 106 shown in FIG. 1. The susceptor 300 includes a base 305 and a recessed area 308 in a central area thereof. The base 305 may be made of deposited SiC, sintered graphite coated with SiC, grown SiC, opaque quartz, coated quartz, or any similar, suitable material that is resistant to chemical breakdown by process and purge gases.

The front side 312 may include a plurality of raised features shown as radially oriented protrusions 310, which may be ribs, extending from the base 305. An upper surface of the protrusions 310 provides a support surface for a substrate (not shown), such that the substrate is spaced form the recess by the thickness of the protrusions 310. The protrusions 310 reduce a contacting surface area between the substrate and the susceptor 300. The protrusions 310 may increase surface area for heat loss (radiation), and may reduce thermal conduction into the edge of the substrate from the susceptor 300.

The backside of the base 305, shown in FIG. 3B, may include raised portions 315, which may be fins. The raised portions 315 may be arcuate, raised structures, and are positioned concentrically on the base 305. In one embodiment, the raised portions 315 comprise concentric arcuate segments. The raised portions 315 increase the surface area of the base 305, which may be utilized to increase absorption of thermal energy to the base 305. Support interface structures 320 may be formed in the backside of the base 305 that interface with the support arms 192 of the substrate support 190 shown in FIG. 1. Optionally or additionally, surfaces of the base 305, such as a peripheral surface 325 and a central surface 330 inside the raised portions 315, may be modified to vary absorption of thermal energy. For example, the surfaces 325 and 330 may be roughened or smoothed in order to increase surface area, or decrease surface area, respectively. In one embodiment, the central surface 330 may be roughened to a degree that is greater than a roughness of the peripheral surface 325 in order to increase absorption of thermal energy in the center of the base 305 relative to the edge of the base 305.

FIG. 3C shows another embodiment of the back side 314 of the susceptor 300. In this embodiment, the back side 314 includes radial fins 335 extending from the surface 330 of the base 305. Roughening of the surfaces 325, 330 may also increase conduction of heat from a substrate (not shown) positioned on the susceptor 300.

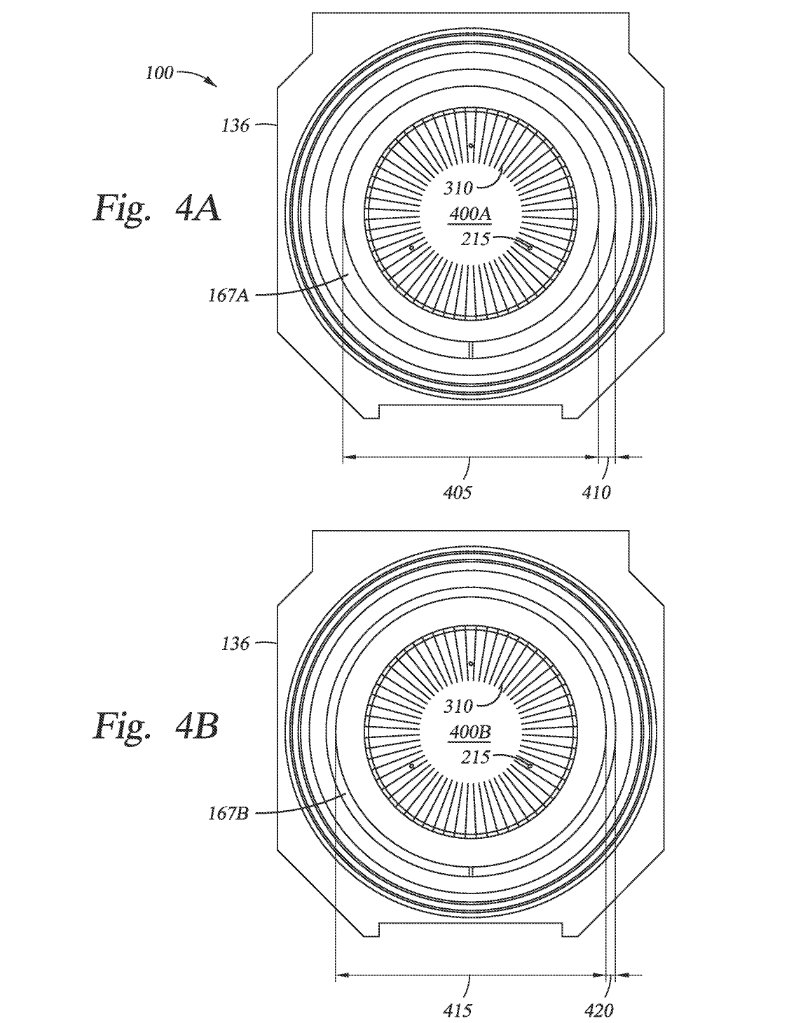

FIG. 4A is a top plan view that shows one embodiment of a susceptor 400A and a circular shield 167A disposed within a base ring 136. The susceptor 400A may be similar to the susceptor 300 shown in FIGS. 3A and 3B, although other susceptors, such as the susceptor 200 shown in FIGS. 2A-2C may be used. The susceptor 400A includes a diameter 405 that may be sized slightly larger than a diameter of a substrate (not shown). The circular shield 167A may include a width 410 that is slightly larger than the diameter 405.

FIG. 4B is a top plan view that shows another embodiment of a susceptor 400B and a circular shield 167B disposed within a base ring 136. The susceptor 400B may be similar to the susceptor 300 shown in FIGS. 3A and 3B, although other susceptors, such as the susceptor 200 shown in FIGS. 2A-2C may be used. In this embodiment, the susceptor 400B has a surface area greater than a surface area of the susceptor 400A shown in FIG. 4A. The susceptor 400B includes a diameter 415 that may be sized slightly larger than a diameter of a substrate (not shown). However, the diameter 415 is greater than the diameter 405 of the susceptor 400A of FIG. 4A. The circular shield 167B may include a width 420 that is slightly larger than the diameter 415. However, the width 420 is less than the width 410 of the circular shield 167A of FIG. 4A. The susceptor 400B provides more surface area which may increase heat loss via conduction, thus reducing temperature at the edge of a substrate (not shown) positioned thereon.

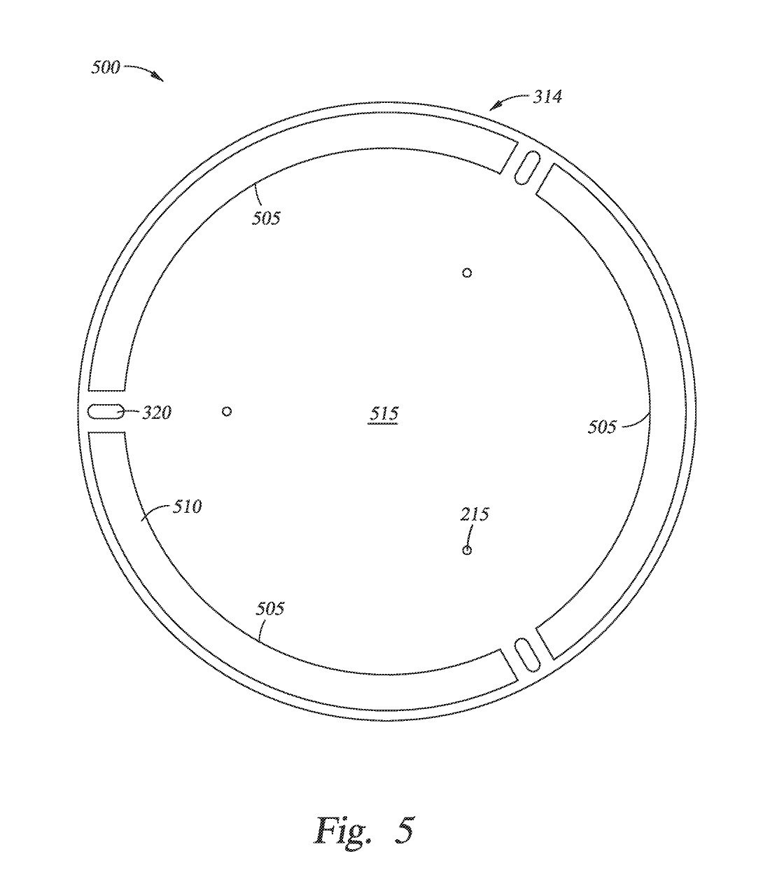

FIG. 5 is a plan view of a back side of 314 another embodiment of a susceptor 500. The susceptor 500 may be utilized as the susceptor 106 shown in FIG. 1. The susceptor 500 may be made of deposited SiC, sintered graphite coated with SiC, grown SiC, opaque quartz, coated quartz, or any similar, suitable material that is resistant to chemical breakdown by process and purge gases. A plurality of arcuate channels 505 are formed in the susceptor 500 according to this embodiment. The arcuate channels 505 may include a depression 510 formed in a surface 515 of the susceptor 500, which minimizes mass at the edge of the susceptor 500. The arcuate channels 505 may improve thermal losses at the edge of the susceptor 500. The arcuate channels 505 may be formed in the back side 314 of the susceptor 500 as shown. Alternatively, the arcuate channels 505 may be formed in a front side of the susceptor 500 (i.e., the side of the susceptor that faces or contacts the substrate (not shown)).

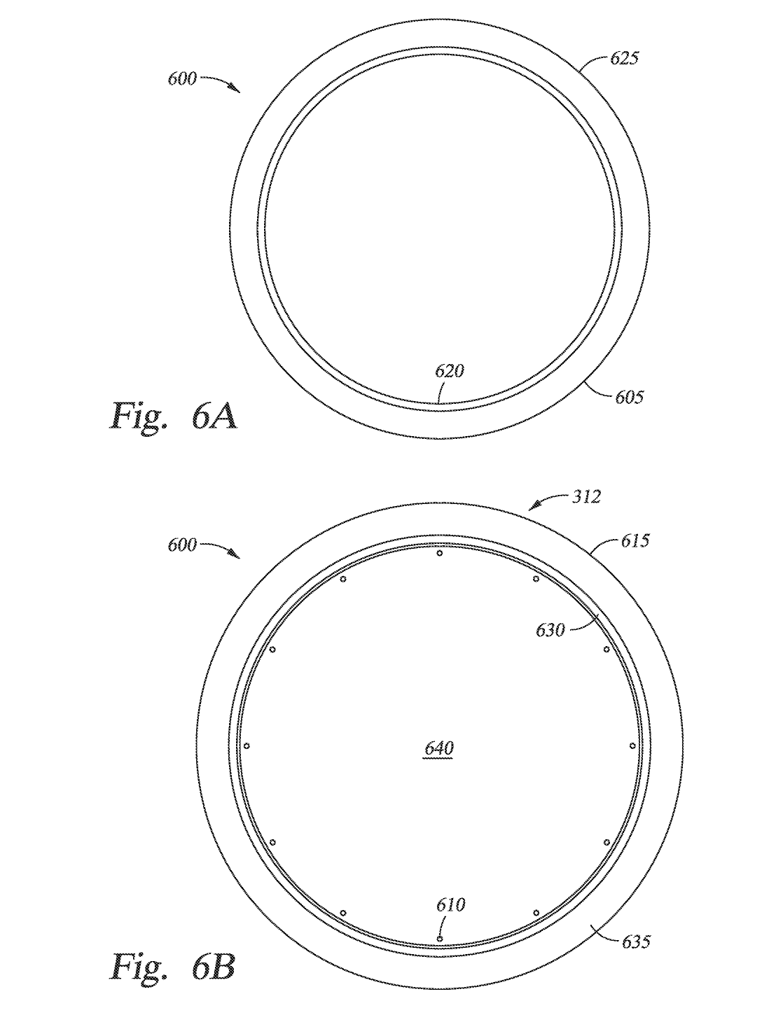

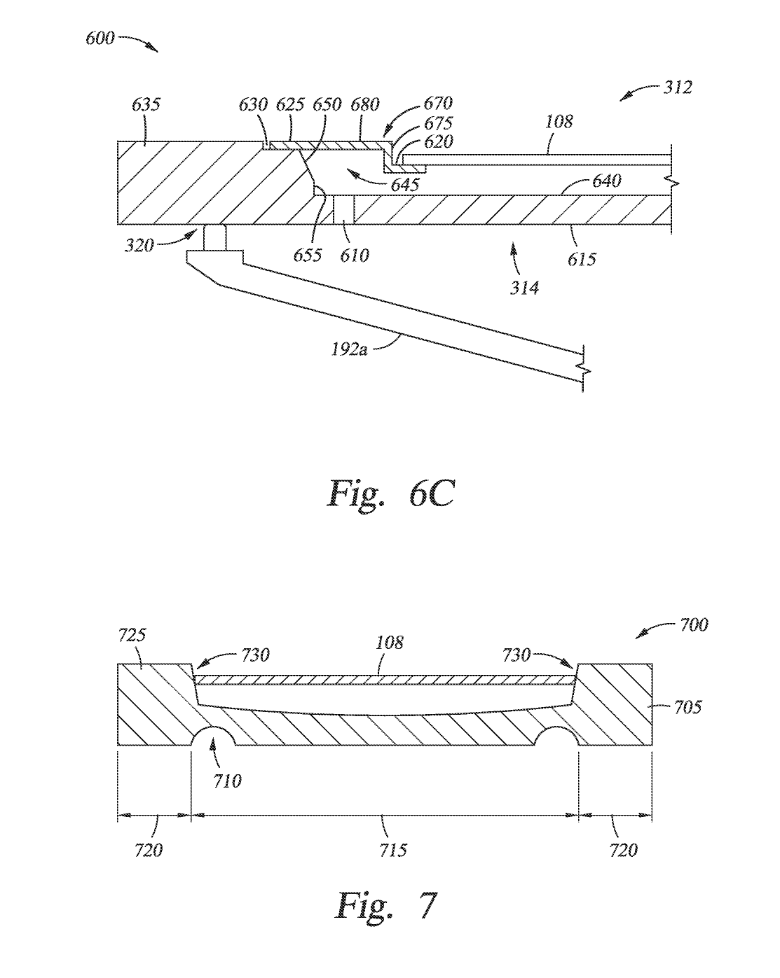

FIGS. 6A-6C are various views of another embodiment of front side a susceptor 600. The susceptor 600 includes a base 615 and a ring 605 that interfaces with the base 615. The base 615 also includes a plurality of holes 610. The base 615 and the ring 605 may be made of similar or different materials, such as deposited SiC, sintered graphite coated with SiC, grown SiC, opaque quartz, coated quartz, or any similar, suitable material that is resistant to chemical breakdown by process and purge gases. The number of holes 610 may be between about 3 and about 120, and may be evenly spaced on the base 615. The ring 605 may include an inner peripheral lip 620 configured to support a substrate (not shown). The ring 605 may also include an outer peripheral edge 625 that interfaces with a insert region 630 of the base 615. The base 615 includes a peripheral region 635 surrounding a recessed area 640. As shown in FIG. 6C, a thickness of the peripheral region 635 is greater than a thickness of the recessed area 640.

The holes 610 may be utilized for venting, which may reduce sliding of a substrate (not shown) induced by an “air pocket” effect during rapid pressure ramp downs. When a substrate is being processed on the susceptor 600, the holes 610 are exposed to the processing environment on the back side 314 of the base 615 which does not see process gases, which prevents deposition on the backside of the substrate. The holes 610 can be normal to the surface of the base 615 as shown, or be angled relative to the surface of the base 615. The ring 605 reduces edge temperature gradient of the substrate by positioning the substrate away from the higher mass area of the base 615 (at the peripheral region 635) of the base 615. The base 615 may have a stepped region 645 as shown in FIG. 6C to reduce misalignment of the ring 605. The stepped region 645 may include one or a combination of the insert region 630, an angled surface 650, and a planar surface 655. The planar surface 655 may be disposed in a plane that is substantially normal to a plane of the recessed area 640. The ring 605 may also include a stepped region 670. The stepped region 670 may include the inner peripheral lip 620 as well as a wall 675 joining the inner peripheral lip 620 with an outwardly extending shoulder 680. A plane of the wall 675 may be substantially normal to a plane of the outwardly extending shoulder 680. Alternatively, the wall 675 may be angled relative to the plane of the outwardly extending shoulder 680.

FIG. 7 is a side cross-sectional view of another embodiment of a susceptor 700. The susceptor 700 may be utilized as the susceptor 106 shown in FIG. 1. The susceptor 700 includes a base 705 made of deposited SiC, sintered graphite coated with SiC, grown SiC, opaque quartz, coated quartz, or any similar, suitable material that is resistant to chemical breakdown by process and purge gases. The base 705 also includes a trench 710 formed therein to provide a thermal break. For example, during processing, the base 705 includes a hot zone 715 adjacent a center thereof. The hot zone 715 is surrounded by a relatively cool zone 720 at a peripheral region 725 thereof. The relatively cooler portion comprising the larger mass of the peripheral region 725 may not promote balanced thermal transport from center to edge. This may promote a contact spot 730 on the substrate 108 that is hotter relative to the center of the substrate 108. Due to the increased temperature relative to the center, the contact spot 730 may promote thicker film deposition as compared to the center of the substrate 108. The trench 710 may partially isolate thermal transport form the hot zone 715 to the cool zone 720. This may reduce the temperature at the contact spot 730 and promote more uniform deposition on the substrate 108. The trench 710 may be continuous or be configured as the arcuate channels 505 of FIG. 5.

Although the foregoing embodiments of exemplary susceptors have been described using circular geometries to be used on semiconductor “wafers,” the embodiments disclosed can be adapted to conform to different geometries.

While the foregoing is directed to typical embodiments, other and further embodiments may be devised without departing from the basic scope thereof, and the scope thereof is determined by the claims that follow.

What is claimed is:

1. A susceptor for a thermal processing chamber, comprising:
a base having a front side and a back side made of a thermally conductive material opposite the front side, wherein the base includes:
a peripheral region surrounding a recessed area having a thickness that is less than a thickness of the peripheral region; and
a plurality of raised features protruding from one or both of the front side and the back side.

2. The susceptor of claim 1, wherein the front side includes the plurality of raised features extending from the recessed area.

3. The susceptor of claim 2, wherein the raised features are radially oriented.

4. The susceptor of claim 2, wherein the raised features are concentric arcuate segments.

5. The susceptor of claim 1, wherein the back side includes a channel formed therein.

6. The susceptor of claim 1, wherein the back side includes the plurality of raised features extending therefrom.

7. The susceptor of claim 6, wherein the plurality of raised features are concentric.

8. The susceptor of claim 6, wherein the raised features are radially oriented.

9. The susceptor of claim 1, wherein the base includes a plurality of holes formed therein inward of the peripheral region.

10. The susceptor of claim 9, wherein the front side includes the plurality of raised features extending from the recessed area.

11. The susceptor of claim 10, wherein the raised features are radially oriented.

12. The susceptor of claim 10, wherein the raised features are arcuate segments concentrically oriented on the base.

13. The susceptor of claim 1, further comprising a ring made of a thermally conductive material, wherein the peripheral region of the base has an insert region to receive the ring.

14. A susceptor for a thermal processing chamber, comprising:
a base made of a thermally conductive material, and having a front side and a back side opposite the front side wherein the base further includes:
a peripheral region surrounding a recessed area having a thickness that is less than a thickness of the peripheral region; and
a plurality of raised features protruding from one or both of the front side and the back side; and
a ring made of a thermally conductive material, wherein the peripheral region has an insert region to receive the ring.

15. The susceptor of claim 14, wherein the base includes a plurality of holes formed therein inward of the peripheral region.

16. The susceptor of claim 15, wherein the front side includes the plurality of raised features extending from the recessed area.

17. The susceptor of claim 15, wherein the raised features are radially oriented.

18. The susceptor of claim 15, wherein the raised features are concentric arcuate segments.

19. A susceptor for a thermal processing chamber, comprising:
a base having a front side and a back side opposite the front side made of a thermally conductive material, wherein the base includes a peripheral region surrounding a recessed area having a thickness that is less than a thickness of the peripheral region; and
a ring made of a thermally conductive material and having a sloped surface formed on an inner circumference thereof to facilitate centering of a substrate thereon, wherein the peripheral region has an insert region to receive the ring.

20. The susceptor of claim 19, wherein the base includes a plurality of holes formed therein inward of the peripheral region.
